(19) United States
(12) Patent Application Publication
(10) Pub. No.: US 2006/0199370 A1
(43) Pub. Date: Sep. 7, 2006

(54) Method of in-situ ash strip to eliminate memory effect and reduce wafer damage

(75) Inventors: Shiau-Ling Dai, Jhubei City (TW); Eric Sun, Zhudong Town (TW)

Correspondence Address: Duane Morris LLP, 4200 One Liberty Place, Philadelphia, PA, 19103-7396, US

(73) Assignee: Taiwan Semiconductor Manufacturing Co., Ltd.

(21) Appl. No.: 11/069,131

(22) Filed: Mar. 1, 2005

(51) Int. Cl. H01L 21/4763

(52) U.S. Cl. 438/624

(57) ABSTRACT

An in-situ ashing method for stripping a photoresist layer following a fluorocarbon based etch that transfers a pattern through a dielectric layer is disclosed. The method is especially effective in removing fluoropolymer residues from substrates with minimal damage to the dielectric layer and an underlying etch stop layer. A first oxygen ashing step is performed with low bias power to remove the residues and a portion of the photoresist. Other oxidizing gases such as CO may be added. Then a second oxygen ashing step with a bias power strips the remaining photoresist. The method also avoids faceting and damage to the dielectric layer adjacent to the opening. Furthermore, a shift in the dielectric constant of the dielectric layer is reduced compared to a single ashing step with a bias power. The in-situ process may further include an additional plasma etch step to remove an etch stop above a conductive layer.

### FIELD OF THE INVENTION

The subject matter relates to the field of integrated circuit fabrication and in particular to a method of removing photoresist and other organic materials from a substrate while minimizing the damage to an underlying dielectric layer or an exposed etch stop layer.

### BACKGROUND

Metal interconnects in a semiconductor device are typically formed by depositing a metal in an opening such as a via, contact hole, or a trench that is formed in one or more dielectric layers. In a single damascene method, a via or contact is filled with a metal and the metal is planarized. In a dual damascene method, a trench and an underlying via are filled simultaneously with metal followed by planarization at the top of the trench. In order to accommodate higher circuit densities for new technologies, the width of the opening must shrink which poses an increasingly difficult challenge for controlling the lithography, etching, and related processes required for building such a device.

The opening in a damascene method is typically formed by coating and patterning a photoresist layer on an interlevel dielectric layer (ILD) or on an intermetal dielectric (IMD) layer and then transferring the pattern through the dielectric layer with a plasma etch process that ends at an etch stop layer such as silicon nitride. ILD and IMD layers are typically comprised of SiO₂ or a low k dielectric material and are etched with a plasma based on a fluorocarbon source gas. In order to provide a high etch selectivity, a passivation layer comprised of a fluorocarbon polymer is usually deposited on the sidewalls of the opening during the etch. Unfortunately, during the step of stripping the photoresist with an oxygen containing plasma, fluorocarbon polymer or fluorine containing residues on the sidewalls of the opening and on the surface of an ILD/IMD layer provide a source of fluorine radicals that attack the surrounding dielectric layer and the etch stop layer. As a result, damage to the top of the dielectric layer occurs in the form of a tapered profile in the opening or a notch adjacent to the opening. Furthermore, the etch stop layer suffers a significant thickness loss which can lead to damage to an underlying metal layer during a subsequent step of removing the etch stop layer at the bottom of the opening.

Another undesirable side effect of a photoresist ashing process is that the dielectric constant of the ILD or IMD layer may shift since erosion of the sidewall allows water generated from the oxygen ashing step to penetrate into the ILD or IMD layer and thereby increasing the k value. A higher k value results in more capacitance coupling between metal interconnects thereby leading to a slower device.

Optionally, a wet photoresist strip is possible but a wet method has several disadvantages. A wet solution is more costly since the waste requires special storage and handling measures. Moreover, after an organic stripper solution is applied, an aqueous cleaning solution usually follows to ensure complete removal of fluorine containing residues. An integrated process flow in a single process chamber that optimizes throughput is not possible with a wet stripper inserted between an ILD/IMD etch and an etch to remove the etch stop layer at the bottom of a damascene opening.

In FIG. 1, a conventional damascene structure is shown partially formed on a substrate 1. A stack comprised of an etch stop layer 2, an ILD layer 3, and a photoresist layer 4 are sequentially formed on the substrate 1. The photoresist layer 4 has been patterned by a lithographic method to form an opening 5 which is typically aligned over a metal layer (not shown) or source/drain region of a transistor (not shown) in the substrate 1. The opening 5 has been transferred through the ILD layer 3 by a plasma etch based on a fluorocarbon chemistry. As a result, fluorocarbon polymer residues 6a are deposited on the sidewalls of the opening 5 and on the surface of the photoresist masking layer 4. Note that fluoropolymer residues 6b are also formed on the process chamber wall 7.

In FIG. 2, a conventional plasma strip or oxygen ashing step is used to simultaneously remove the photoresist layer 4 and fluoropolymer residues 6a, 6b. The fluoropolymer residue 6b is stripped to prevent a buildup of the fluorine containing residue that requires frequent and expensive chamber cleaning operations for preventative maintenance. Typically, the oxygen ashing process involves a bias power that induces a sputtering component to the plasma which increases the fluoropolymer residue removal rate for higher throughput. However, damage to the damascene structure occurs as shown by a top corner loss 8 on the opening 5 and a thickness loss 9 on the exposed etch stop layer 2 due to the reactive nature of a plasma that has both fluorine and oxygen radicals. As previously mentioned, the dielectric constant of the ILD layer 3 is also shifted by incorporation of moisture during the etch process.

Therefore, an improved photoresist stripping process is needed that mitigates the effect of fluorine containing residues on an underlying ILD or IMD layer and etch stop layer. The ideal stripping process is an in-situ ashing method comprising an etching step in which the fluorocarbon etches through the ILD or IMD layer, a photoresist ashing step, and a subsequent etching step which removes a stop layer. It is envisioned that the aforementioned steps may all be performed in the same process chamber.

U.S. Pat. No. 6,207,565 discloses an oxide layer over a gate stack that is etched by a fluorocarbon plasma. First, contaminants on the substrate surface are removed by a plasma generated from water and a fluorocarbon. Then, the photoresist mask is stripped by O₂ ashing. A 15% reduction in sheet resistance is observed.

A process for ashing organic materials is described in U.S. Pat. No. 6,231,775 in which a SO₃ based plasma is used alone or with other gases preferably at less than 200° C. However, SO₃ requires special handling with respect to storage, delivery, and temperature control within a process chamber.

An example of the present subject matter provides an ashing method for removing an organic layer from a substrate that reduces the amount of faceting and thickness loss in an underlying dielectric layer. The present subject matter also provides a method of removing fluoropolymer residues from a photoresist masking layer and from an opening in a dielectric layer that will minimize thickness loss in an exposed etch stop layer at the bottom of the opening.

An example of the present subject matter further provides an ashing method for removing an organic layer that reduces the amount of shift in dielectric constant for an underlying and patterned dielectric layer trench pattern that is generated in the second photoresist layer and is transferred into the dielectric layer above the via by a second fluorocarbon etch that produces fluoropolymer residues. The ashing method of the first embodiment is repeated at this point to remove the fluorocarbon residues and then strip the second photoresist layer in the same process chamber in which the second fluorocarbon etch is carried out. The in-situ process concludes by removing the etch stop layer in the same process chamber used to ash the second photoresist layer.

These and other advantages of the disclosed subject matter will be readily apparent to one skilled in the art to which the disclosure pertains from a perusal or the claims, the appended drawings, and the following detailed description of the preferred embodiments.

### BRIEF DESCRIPTION OF THE DRAWINGS

FIGS. 1-2 are cross-sectional views depicting a prior art method of ashing a photoresist layer and removing fluoropolymer residues from an opening in a dielectric layer that is formed over an etch stop layer.

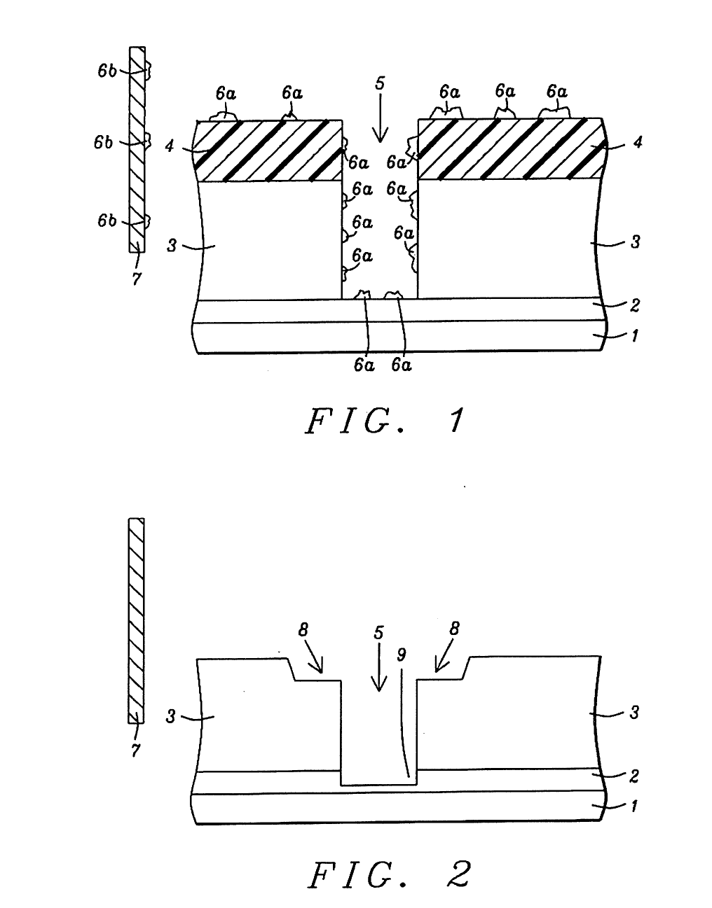

FIG. 3 is a cross-sectional view that shows a split power RIE etcher on the left and a dual power RIE etcher on the right.

FIGS. 4-6 are cross-sectional views that illustrate a sequence of steps for removing fluoropolymer residue from a substrate and then stripping a photoresist layer from above a dielectric layer according to an embodiment of the present subject matter.

FIG. 7 is a cross-sectional view that shows the removal of the exposed etch stop layer in FIG. 6 which is performed in the same process chamber as the photoresist stripping according to one embodiment of the present subject matter.

FIGS. 8-11 are cross-sectional views that illustrate a method for removing fluoropolymer residue and stripping a photoresist layer on a dielectric layer in which a trench is formed above a via according to a second embodiment of the subject matter.

### DETAILED DESCRIPTION OF THE SUBJECT MATTER

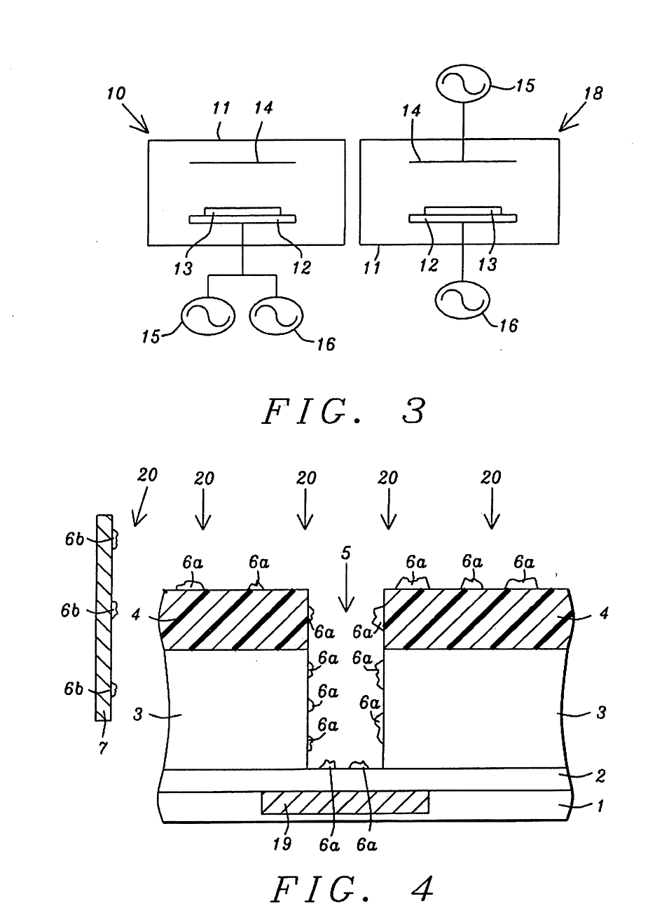

The present subject matter is a particularly useful method for removing organic materials including a photoresist masking layer following a fluorocarbon based plasma etch through an underlying dielectric layer. Although the method is incorporated into a single damascene scheme in the first embodiment, the method also applies to other manufacturing process flows in which a photoresist mask is employed for a fluorocarbon based etch that transfers a pattern through one or more underlying layers and generates fluorocarbon residues in pattern openings and on the photoresist mask. It should be understood that the method of the present subject matter may be performed in a variety of plasma etch chambers. In FIG. 3, two possible configurations of a reactive ion etch (RIE) chamber are shown. On the left, a split power RIE etcher 10 includes a chamber 11, an electrostatic chuck 12 which holds a wafer 13, a top electrode 14, a high frequency power source 15, and a low frequency power source 16 which is used to apply a bias power. The electrostatic chuck 12 also serves as a bottom electrode. On the right, a dual power RIE etcher 18 is shown having the same elements as previously mentioned for the split power RIE etcher 10 except the high frequency power source 15 is applied at the top electrode 14 while the low frequency power source 16 is applied at the bottom electrode 12. Furthermore, the subject matter may be carried out in any of the conventional barrel, direct, or downstream type of ashing tools known to those who practice the art.

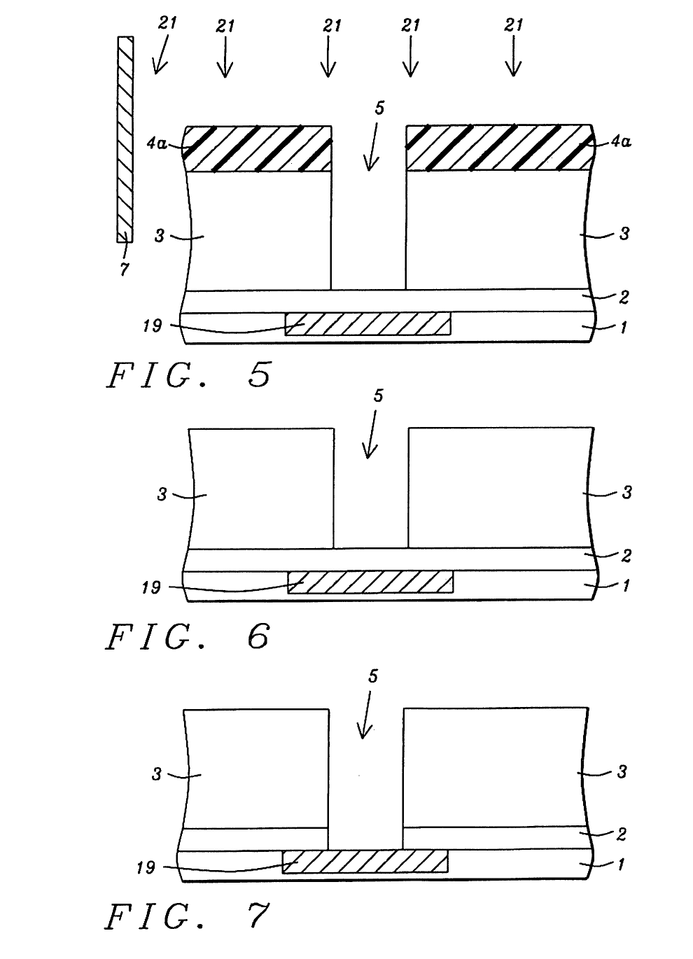

A first embodiment is illustrated in FIGS. 4-7. Referring to FIG. 4, a substrate 1 is provided that is typically silicon but may also be based on silicononinsulator, silicon germanium, or galliumarsenide technology. The substrate 1 typically contains active and passive devices (not shown). A conductive layer 19 typically comprised of Cu, AI/Cu, AI, or W, for example, is formed in the substrate 1 by a conventional method and has a top surface that is coplanar with the substrate 1. When the conductive layer 19 is copper, the layer may be enclosed on the sides and bottom by a thin diffusion barrier layer (not shown) which protects the copper from corrosion and prevents copper ions from migrating into adjacent regions of the substrate 1.

An etch stop layer 2 with a thickness of about 400 to 800 Angstroms is deposited on the substrate 1 and is preferably comprised of silicon nitride, silicon carbide, or silicon oxynitride. The etch stop layer 2 protects the conductive layer 19 during subsequent processing to form an opening 5 above the conductive layer 19. Next, a dielectric layer 3 having a thickness between about 4800 and 9600 Angstroms is deposited on the etch stop layer 2 by a chemical vapor deposition (CVD), plasma enhanced CVD technique, or by a spin-on method. In one embodiment, the dielectric layer 3 is SiO₂, phosphosilicate glass (PSG), or borophosphosilicate glass (BPSG). Alternatively, the dielectric layer 3 is comprised of a low k dielectric material such as fluorine doped SiO₂ also known as FSG, carbon doped SiO₂, a silsesquioxanepolymer, a fluorinated polyimide, benzocyclobutene, or a poly(arylether). When a low k dielectric layer 3 is employed, the dielectric layer may be cured by baking at a temperature of up to about 4500 C. Additionally, a low k dielectric layer 3 may be densified by a plasma treatment known to those skilled in the art to harden the layer and stabilize the low k dielectric material so that the k value does not shift due to absorption of moisture during exposure to air or subsequent processing.

A first photoresist layer 4 is coated on dielectric layer 3 and is patterned with a conventional lithography process to form an opening 5 which may be a contact hole, via, or a trench. In the illustrated example, the opening 5 is a via in a single damascene scheme. However, the present subject matter is equally effective when the conductive layer 19 is a metal silicide formed on a gate electrode or on a source/drain region in a transistor. In that case, the opening 5 is considered a contact hole in which a metal interconnect will be formed. Optionally, an antireflective coating (ARC) (not shown) is formed on the dielectric layer 3 before the first photoresist layer 4 is coated in order to provide a larger process window during the patterning step. An organic ARC is typically comprised of a polymer that is cross linked after the coating step by heating to a temperature of about 200° C. to 250° C. However, an ARC may also be an inorganic layer such as silicon oxynitride that also serves as a stop layer during a subsequent planarization step in which a metal layer is deposited in the opening 5.

The substrate 1 with the patterned first photoresist layer 4 is placed in a process chamber in an etch tool. Note that only a portion of the process chamber wall 7 is shown. A plasma etch based on a fluorocarbon gas is performed to transfer the opening 5 anisotropically through the dielectric layer 3. In an alternative embodiment where an ARC is formed below the first photoresist layer 4, a first plasma etch step may involve an ARC opening step followed by the fluorocarbon etch through the dielectric layer 3.

For example, if an organic ARC is employed, then the first etch step may include O₂ and Ar to remove the ARC at the bottom of the opening 5 and thereby uncover the dielectric layer 3. A fluorocarbon based etch may be defined as a plasma etch comprised of one or more CₓF_{y}H_{z} gases where x and y are integers and z is an integer or is equal to 0. A fluorocarbon based etch may further include other gases such as H₂, an inert gas, an oxygen containing gas, or a nitrogen containing gas.

In addition to a main fluorocarbon based etch step through the dielectric layer 3, the subject matter anticipates a subsequent over etch step that is also fluorocarbon based and is performed immediately following the main fluorocarbon etch. An over etch step ensures that all the dielectric layer 3 is removed within the opening 5 and that other openings (not shown) within the photoresist pattern are completely transferred through the dielectric layer 3.

The over etch step does not necessarily include the same gases that are used in the main etch step. Note that other openings may have a different width or a different pattern density than the opening 5 which is pictured as an isolated opening. Thus, the etch rate through the dielectric layer 3 to generate the opening 5 is likely to be different than the etch rate through other portions of the dielectric layer 3 with different sized openings or where openings are formed in dense arrays.

In an exemplary process that is not meant to limit the scope of the subject matter, the opening 5 is transferred through the dielectric layer 3 with the following three step sequence in a process chamber. First, a de-scum step involving an O₂ flow rate of about 150 standard cubic centimeters per minute (sccm), an Ar flow rate of about 150 sccm, a 20 mTorr chamber pressure, a low frequency RF (LFRF) power of 500 Watts, and a high frequency RF (HFRF) power of 150 Watts is performed for 5 seconds. The main etch step comprises a C₅F₈ flow rate of 14 sccm, a CHF₃ flow rate of 60 sccm, an Ar flow rate of 900 sccm, an O₂ flow rate of 52 sccm, a 35 mTorr chamber pressure, a LFRF power of 2800 Watts, and a HFRF power of 3800 Watts for about 80 seconds. The third step is an over etch step that includes a C₅F₈ flow rate of 30 sccm, an Ar flow rate of 1100 sccm, an O₂ flow rate of 50 sccm, a chamber pressure of 30 mTorr, a LFRF power of 2800 sccm, and a HFRF power of 3800 sccm for a period of about 60 seconds.

As a result of the fluorocarbon based etch through the dielectric layer 3, fluoropolymer residues 6a are formed within and adjacent to the opening 5 and fluoropolymer residues 6b are deposited on the chamber wall 7. Although fluoropolymer residues 6a, 6b are depicted as an incomplete covering, in some situations a continuous fluoropolymer residue 6a, 6b may form which leaves no exposed portions of the chamber wall 7, photoresist layer 4, dielectric layer 3, or etch stop layer 2. Those skilled in the art will appreciate that small amounts of other elements such as H, S, N, and O may be trapped within the fluoropolymer residues 6a, 6b since some of the byproducts from the fluorocarbon etch of the dielectric layer 3 may react with fluorine radicals or CₓF_{y}H_{z} radical species and be co-deposited with the fluorocarbon residue.

A feature of the present subject matter is an oxygen ashing sequence that removes the fluoropolymer residues 6a, 6b and the first photoresist layer 4 with minimal damage to the dielectric layer 3 or to the etch stop layer 2. The oxygen ashing is preferably carried out in the same process chamber that was used for the previously described fluorocarbon etch sequence. The first step of the two step oxygen ashing sequence involves a plasma 20 that is generated with the following process conditions: a 100 to 500 sccm CO flow rate; a 300 to 1500 sccm O2 flow rate; a chamber pressure of about 15 to 500 mTorr, a HFRF power from about 500 to 2500 Watts, low bias power, and a chamber temperature of about 20° C. to 80° C. for a period of about 10 to 60 seconds. Low bias power is defined, for purposes of this disclosure, as not greater than 150 Watts. Preferred conditions are a 200 sccm CO flow rate, a 600 sccm O₂ flow rate, a 20 mTorr chamber pressure, a 60° C. chamber temperature, a HFRF power of 650 Watts, and low bias power for about 30 seconds. Under the preferred conditions, the first photoresist layer 4 is thinned at about 2000 Angstroms per minute. The plasma 20 removes all fluoropolymer residues 6a, 6b from within the process chamber and the byproducts are expelled through an exit port (not shown). It is also envisioned that the exit port may be connected to a vacuum means to assist in expelling the byproducts.

It should be understood that while the preferred first oxygen ashing step includes both O₂ and CO gases, other alternatives are acceptable. For instance, the oxidizing gas used to form the plasma 20 may be only O₂ or only CO. Optionally, the oxidizing gas may comprise one or more of ozone, N₂O, CO₂, H₂O₂ or any other species which can react with fluorine to reduce the memory effect.

Referring to FIG. 5, fluoropolymer residues 6a, 6b have been removed from the thinned first photoresist layer 4a, dielectric layer 3, and etch stop layer 2. Note that a thinned photoresist layer 4a still covers the dielectric layer 3. Although the etch stop layer 2 is shown completely intact, some thickness loss may occur although the amount of thinning is less than results from a conventional oxygen ashing that includes a bias power. For example, when the etch stop layer 2 is silicon nitride and the opening 5 is a via, then the preferred first oxygen ashing step causes a silicon nitride thickness loss from 130 to 170 Angstroms depending on the location of the opening on the substrate. In comparison, a 210 to 230 Angstrom silicon nitride thickness loss is realized when a bias power of 500 Watts is used in combination with conditions cited for the first oxygen ashing step. Similarly, when the opening 5 is a seal ring, the amount of SiN loss is decreased from a range of 270 to 340 Angstroms when a 500 Watt bias power is used in combination with the first oxygen ashing step to only 210-250 Angstroms when a low bias power is applied with the first oxygen ashing step. Therefore the subject matter provides a significant improvement in minimizing thickness loss in an etch stop layer 2 by incorporating a first ashing step of a photoresist layer on any overlying dielectric layer with low bias power.

A second step in the oxygen ashing sequence is now performed and involves a plasma 21 that is generated with the following conditions: a 100 to 500 sccm CO flow rate; a 300 to 1500 sccm O₂ flow rate; a camber pressure of approximately 15 to 500 mTorr, a HFRF power from approximately 500 to 2500 Watts, a LFRF power from approximately 200 to 1200 Watts, and a chamber temperature of 20 C to 80 C for a period of approximately 30 to 120 seconds. Preferred conditions include a HFRF power of 650 Watts, and a LFRF or bias power of 500 Watts for approximately 50 seconds. The 50 second time period represents a 100% overetch to account for first photoresist layer 4a thickness variation across the wafer. Under the preferred conditions, the thinned first photoresist layer 4a is etched at a rate of 6500 Angstroms per minute.

Referring to FIG. 6, the plasma 21 has completely stripped the first photoresist layer 4a from above the dielectric layer 3. In one embodiment where an organic ARC is located between the dielectric layer 3 and the first photoresist layer 4a, the organic ARC is also removed by the second ashing step. Alternatively, when an inorganic ARC such as silicon oxynitride is employed, then the inorganic ARC may remain on dielectric layer 3 as a stop layer for a subsequent planarization step.

One advantage of the two step oxygen ashing sequence of the present subject matter is that damage to the etch stop layer 2 is minimized compared to a single ashing step that has a bias power. For example, when the etch stop layer 2 is silicon nitride and the opening 5 is a via in a single damascene scheme, the preferred conditions that produce the plasmas 20, 21 result in a 190 to 210 Angstrom thickness loss of the silicon nitride layer after two ashing steps which is significantly less than when a one step ash with a 500 W bias power is employed. The greater thickness retention prevents the plasma generated with a bias power condition from punching through the silicon nitride layer and damaging the underlying conductive layer 19. Note that a thicker silicon nitride layer or thicker etch stop is often not an option since most etch stop materials have a relatively high dielectric constant compared to SiO₂. A thicker etch stop layer 2 will only compromise the effect of implementing a low k dielectric material in the dielectric layer 3.

Another benefit of the present subject matter is that faceting and damage to the top of dielectric layer 3 is minimized. In other words, the notches 8 formed adjacent to opening 5 in the dielectric layer 3 in a prior art method shown in FIG. 2 are essentially avoided. Furthermore, the dielectric constant of the dielectric layer 3 is shifted to a lesser extent than when a single step ashing with a bias power is carried out. In the prior art, the k value for the FSG layer increases because of water uptake in an oxygen ash with bias due to the fact that the reaction 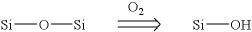
easily absorbs water.

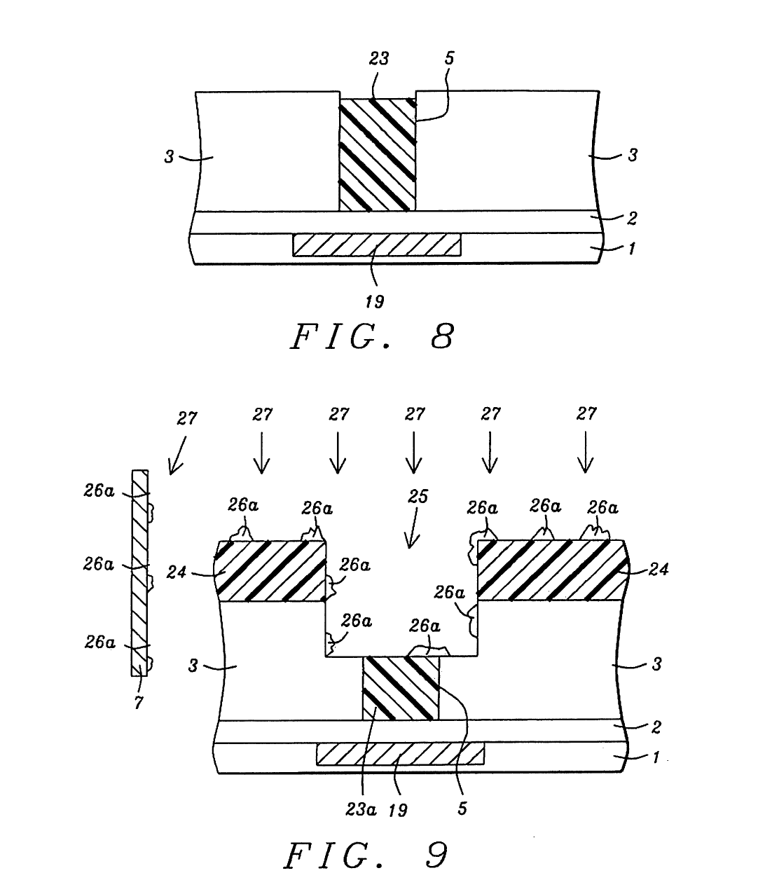

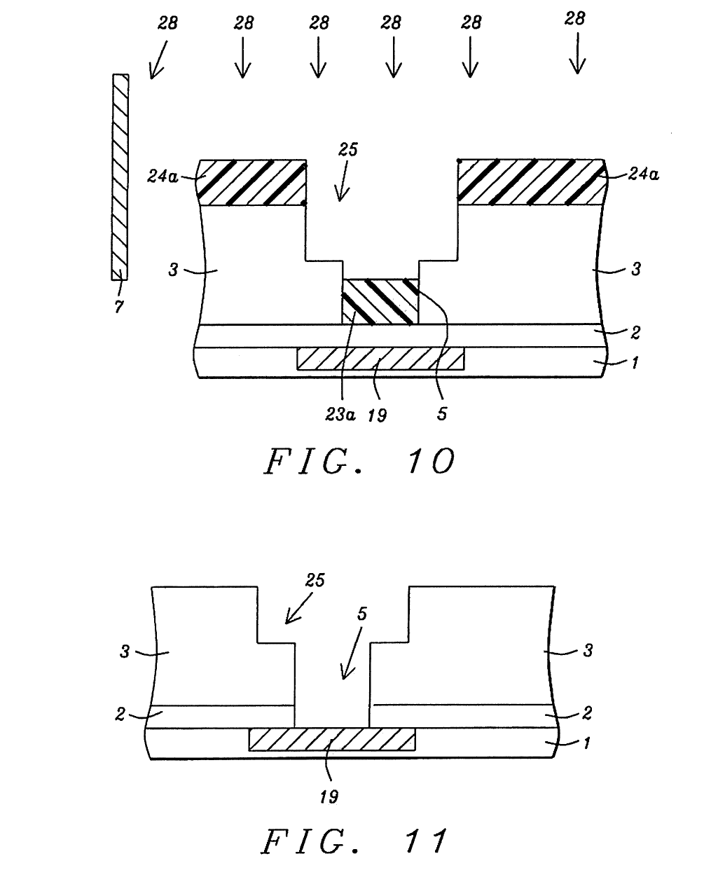

Referring to FIGS. 7-9, the damascene scheme may be continued in the same process chamber in which the fluorocarbon based etch and the two oxygen ashing steps were conducted in the first embodiment. A second oxygen ashing sequence involving a first ashing step comprising a plasma 27, which is preferably the same process as previously described for plasma 20, is performed to remove fluoropolymer residues 26a, 26b. Low bias power is employed and the third photoresist layer 24 is thinned at about 2000 Angstroms per minute. The second oxygen ashing sequence is preferably carried out in the same process chamber as the second fluorocarbon etch.

Referring to FIG. 10, all fluoropolymer residues 26a, 26b have been removed from within the process chamber and the byproducts expelled through an exit port (not shown). Note that a top portion of an inert plug layer 23a may also be removed by the first ashing step so that the inert plug layer 23a becomes recessed slightly in the via 5 below the trench 25. A thinned third photoresist layer 24a remains on the dielectric layer 3. A second oxygen ashing step in the second ashing sequence is now performed and involves a plasma 28 that is preferably generated using the same conditions as described previously with regard to plasma 21.

Referring to FIG. 11, the plasma 28 has completely stripped the thinned third photoresist layer 24a from above the dielectric layer 3 and has removed the inert plug layer 23a from the via 5. In a further embodiment where an organic ARC is located between the dielectric layer 3 and the third photoresist layer 24a, the organic ARC may also be removed by the second ashing step. Alternatively, when an inorganic ARC such as silicon oxynitride is employed, then the inorganic ARC may remain on the dielectric layer 3 as a stop layer for a subsequent planarization step. The dual damascene scheme may now be completed by methods known to those skilled in the art such as deposition of a diffusion barrier layer on the sidewalls and bottom of the via and trench, deposition of a metal layer to simultaneously fill the via and trench openings, and planarization of the metal layer.

The advantages of the second oxygen ashing sequence and in particular the low bias first ashing step are the same as the benefits described for the first oxygen ashing sequence in the first embodiment. Although the etch stop layer thickness is likely to be thinned more by exposure to two oxygen ashing sequences, the combined thinning in the present subject matter is less than observed when two conventional oxygen ashing steps with bias power are performed in a dual damascene process flow. Similarly, damage to a dielectric layer is minimized by implementing the first and second oxygen ashing sequences of the present subject matter compared to a dual damascene approach where conventional biased ashing steps are employed to strip a photoresist mask with a via pattern and subsequently strip another photoresist mask with a trench pattern.

While this subject matter has been particularly shown and described with reference to, the preferred embodiments thereof, it will be understood by those skilled in the art that various changes in form and details may be made without departing from the spirit and scope of this subject matter. For example, the dual damascene process flow of the second embodiment may be repeated a plurality of times to form a stack of metal layers on a substrate.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What we claim is:

1. An ashing method to remove a patterned photoresist layer from a substrate wherein a first layer, and a patterned photoresist layer are sequentially formed on a substrate, and an etch is performed in a process chamber to transfer the photoresist pattern through the first layer, said etch producing residues on said substrate, comprising:
(a) performing a first oxygen containing ashing step with a low bias power in the process chamber to remove said residue; and,
(b) performing a second oxygen containing ashing step with bias power in said process chamber to strip said patterned photoresist layer.

2. The method of claim 1, wherein the step of performing an etch comprises performing a fluorocarbon based etch.

3. The method of claim 1 wherein said first oxygen containing ashing step and the second oxygen containing ashing step are performed in-situ.

4. The method of claim 1, wherein the first layer is a dielectric layer.

5. The method of claim 4 wherein the dielectric layer is selected from the group of SiO₂, phosphosilicate glass (PSG) and borophosphosilicate glass (BPSG).

6. The method of claim 4 wherein the dielectric layer is comprised of a low k dielectric material selected from the group of fluorine doped silicate glass (FSG), carbon doped silicate glass, a silsesquioxane polymer, benzocyclobutene, a fluorinated polyimide, and a poly(arylether).

7. The method of claim 1 wherein the first oxygen containing etch is at low bias power and has a duration of 10 to 60 seconds.

8. The method of claim 1 wherein said process chamber is part of a split power RIE etcher or a dual power RIE etcher.

9. The method of claim 1 wherein said low bias power is less than 150 W.

10. The method of claim 1 wherein said low bias power is zero.

11. The method of claim 1 wherein the first oxygen containing etch is at low bias power and has a duration of 10 to 60 seconds.

12. An ashing method to remove a patterned photoresist layer from a substrate wherein a dielectric layer, and a patterned photoresist layer are sequentially formed on a substrate and a etch is performed in a process chamber to transfer the photoresist pattern through the dielectric layer comprising:
(a) performing a first oxygen containing ashing step with a low bias power less than 150 W in the process chamber to remove said residue; and,
(b) performing a second oxygen containing ashing step with bias power in said process chamber to strip said patterned photoresist layer.

13. The method of claim 12 wherein the dielectric layer is comprised of a low k dielectric material.

14. The method of claim 12, wherein the a ARC layer is provided between the dielectric layer and the patterned photoresist layer.

15. An integrated etch method in a process chamber during a damascene process flow, comprising:
(a) providing a substrate upon, a first layer, and a patterned photoresist layer are formed; said patterned photoresist layer having an opening;
(b) performing an etch in which said opening is transferred through said first layer, said etch produces residues within and adjacent to the opening and on the process chamber wall;
(c) performing a first oxygen ashing step with a bias power in the process chamber to remove residues; and,
(d) performing a second oxygen ashing step to strip said photoresist layer.

16. The method of claim 15, wherein the a ARC layer is provided between the first layer and the patterned photoresist layer.

17. The method of claim 16 further comprising the step of removing said ARC during the second oxygen ashing step.

18. The method of claim 15, wherein said bias power is less than 150 W.

19. The method of claim 15, wherein said bias power is zero.

20. The method of claim 15 wherein said process chamber is part of a split power RIE etcher or a dual power RIE etcher.
